(19) United States
(12) Patent Application Publication
(10) Pub. No.: US 2025/0273607 A1
(43) Pub. Date: Aug. 28, 2025

(54) METHODS AND ARCHITECTURES FOR SHALLOW FIDUCIAL AND METAL DEFINED PAD DESIGNS

(71) Applicant: Intel Corporation, Santa Clara, CA (US)

(72) Inventors: Xiao Liu, Chandler, AZ (US); Bohan Shan, Chandler, AZ (US); Haobo Chen, Chandler, AZ (US); Gang Duan, Chandler, AZ (US); Xiyu Hu, Phoenix, AZ (US); Jose Fernando Waimin Almendares, Gilbert, AZ (US); Bin Mu, Tempe, AZ (US); Yiqun Bai, Chandler, AZ (US); Hongxia Feng, Chandler, AZ (US); Sheng Li, Gilbert, AZ (US); Kyle J. Arrington, Gilbert, AZ (US); Ryan Joseph Carrazzone, Chandler, AZ (US); Srinivas Venkata Ramanuja Pietambaram, Chandler, AZ (US); Xiaoying Guo, Chandler, AZ (US); Dingying Xu, Chandler, AZ (US); Jeremy D. Ecton, Gilbert, AZ (US); Brandon Christian Marin, Gilbert, AZ (US); Ziyin Lin, Chandler, AZ (US); Hiroki Tanaka, Gilbert, AZ (US)

(73) Assignee: Intel Corporation, Santa Clara, CA (US)

(21) Appl. No.: 18/586,027

(22) Filed: Feb. 23, 2024

(51) Int. Cl. H01L 23/00

(52) U.S. Cl. CPC H01L 24/05; H01L 24/03; H01L 24/06; H01L 24/16; H01L 2224/03515; H01L 2224/03614; H01L 2224/05007; H01L 2224/05015; H01L 2224/05147; H01L 2224/05541; H01L 2224/05555; H01L 2224/05557; H01L 2224/05644; H01L 2224/05655; H01L 2224/05664; H01L 2224/05691; H01L 2224/0603; H01L 2224/16227; H01L 2924/3512

(57) ABSTRACT

Methods and architectures for shallow fiducial and metal defined pad designs. Embodiments utilize a thinnable dielectric process. The architecture includes a substrate comprising a dielectric material with one or more conductive contacts on the surface. A layer of a thinnable dielectric or non-conductive material is over the substrate and over the one or more conductive contacts. The layer of dielectric or non-conductive material has a thinned region around individual conductive contacts. The thinned region has a thickness of 4 to 5 microns.

### BACKGROUND

Semiconductor packaging designs, such as shallow fiducials (fid) or metal-defined (MD) pads, present technical challenges related to loss tolerances or targets for an intended peripheral component interconnect (PCI) structure. For example, the shallow fid readings can be adversely impacted when copper (Cu) is oxidized, and cracks in dielectric material around the MD pads can occur during stress testing. Accordingly, methods and architectures that improve shallow fid design and MD pad design are desirable.

### BRIEF DESCRIPTION OF THE DRAWINGS

FIG. 1 illustrates generalized architectural stages resulting from a thinnable resist develop process, in accordance with various embodiments.

FIG. 2 illustrates generalized architectural stages in a proposed shallow fiducial manufacturing process, in accordance with various embodiments.

FIG. 3, FIG. 4A and FIG. 4B illustrate generalized architectural stages in a proposed MD pad patterning manufacturing process, in accordance with various embodiments.

FIG. 5 illustrates an example method using thinnable resist for shallow fiducials and/or MD pad patterning, in accordance with embodiments described herein.

FIG. 6 is a top view of a wafer and dies that may be included in any of the embodiments disclosed herein.

FIG. 7 is a simplified cross-sectional side view showing an implementation of an integrated circuit on a die that may be included in any of the embodiments disclosed herein.

FIG. 8A-8D are simplified perspective views of example planar, FinFET, gate-all-around, and stacked gate-all-around transistors, as may be implemented in various embodiments.

FIG. 9 is a cross-sectional side view of a microelectronic assembly that may include any of the embodiments disclosed herein.

FIG. 10 is a block diagram of an example electrical device that may include any of the embodiments disclosed herein.

### DETAILED DESCRIPTION

Semiconductor packaging designs, such as shallow fiducials (shallow fid) or metal-defined (MD) pads, present technical challenges related to loss tolerances or targets for an intended peripheral component interconnect (PCI) structure. In the case of a shallow fid, bare copper (Cu) is within a fid area and may be oxidized rapidly, causing difficulties for fid reading. In the case of MD pads, solder resist (SR) is directly laminated on a dielectric (e.g., Ajinomoto build-up film (ABF)) in the MD pad region. The SR thickness can be large enough (e.g., >33 um) that no bottom reflection occurs, causing an insufficient UV cure at SR bottom. This insufficient UV cure at the SR bottom can lead to a “gap” or SR undercut (see, FIG. 4A, arrow 462 to indicate where this can occur). The SR undercut can be sufficiently large enough to void reliable contacts, such as, for a ball grid array (BGA), and/or to result in cracks in the ABF at the MD pad area. During temperature cycling tests, MD pads located in high stress regions experience tensile stress, often leading to an ABF crack and/or pinch-points at the MD pads. Upon analysis of these MD pads, the full removal of the SR often reveals that the ABF is in direct contact with solder balls, which causes a solder paste/flux wetting behavior difference, thus leading to what people with skill in the art refer to as a solder ball “satellite issue.”

One proposed solution implements an organic surface protection (OSP) layer. The material used for the OSP layer is generally a small-molecule organic material, such as an imidazole-based material. However, OSP is not sufficient to protect Cu from oxidation under ambient environment, which causes a difficulty for fid reading. Accordingly, methods and architectures that improve shallow fid design and MD pad design are desirable.

Embodiments disclosed herein propose a technical solution to the above-described technical problems in the form of methods and architectures for shallow fid design and MD pad design. The proposed method implements a thinnable solder resist (SR); resulting architectures include a thin layer of solder resist (SR) at the fid area and at the MD pad area. The thin layer of SR functions as a protective layer that improves fid recognition because it averts the oxidation of the copper (Cu) in the shallow fid designs. The thin layer of SR can eliminate the SR undercut phenomenon since there is no exposure of dielectric (e.g., ABF) in the ball attach process, as a result, the solder ball satellite issue is resolved. Additionally, the thin layer of SR in MD pad designs mitigates the crack risk surrounding the MD pads. These concepts are developed in more detail below.

Embodiments can be identified with scanning electron microscopy (SEM) images, generally with a cross-sectional inspection and a top-down SEM. Embodiment features include, for a shallow fid design, a thin layer of non-conductive material or solder resist on top of a copper pad/conductive contact; and, for a MD pad design, a thin layer of non-conductive material on top of dielectric/ABF around a copper pad/conductive contact. Notably missing in the embodiments will be the SR undercut at the bottom of the sidewalls around the copper pad/conductive contact.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

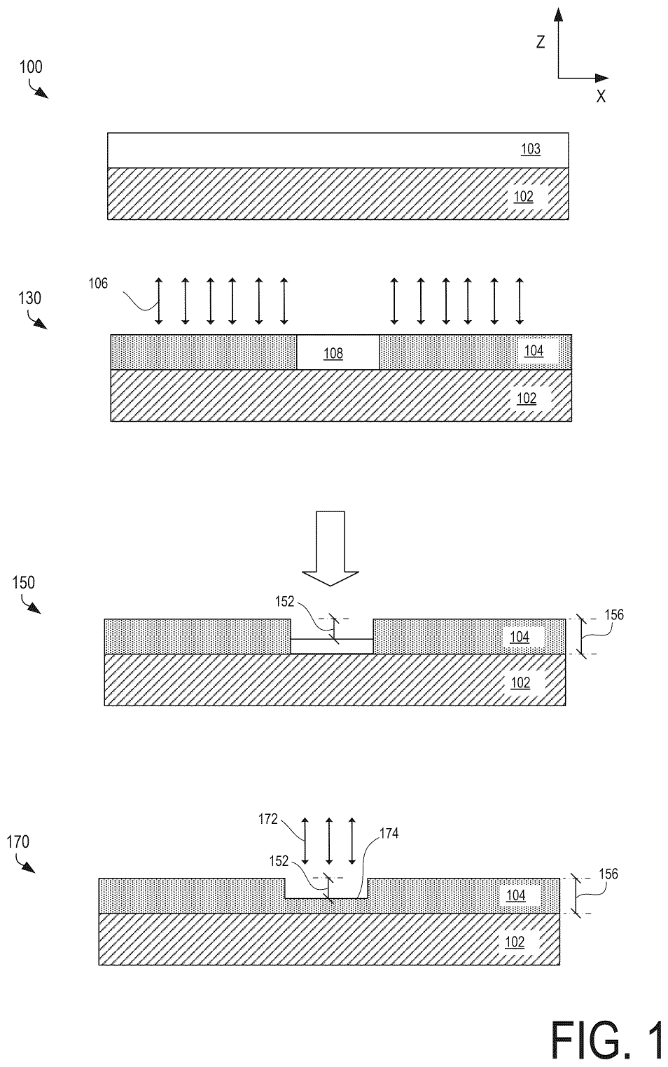

FIG. 1 illustrates generalized architectural stages resulting from a thinnable resist develop process. FIG. 1 illustrations are cross-sectional images, with a Z-X frame of reference, as indicated. Embodiment 100 shows a layer of uncured thinnable resist 103 directly laminated on (alternatively, overlaid on, or simply “on”) an upper surface of a substrate material 102. As mentioned above, the “thinnable resist” is a solder resist (SR) and may be referred to simply as a SR for simplicity. SR is an electrical insulating material, so it prevents electrical current from flowing. Examples of material used for SR include polyimide or a similar material. In various embodiments, the substrate material 102 is ABF. Embodiment 130 illustrates ultra-violet (UV) 106 exposure on the upper surface of the SR 103. As may be appreciated, the UV exposure is selective, and a mask is generally used to generate the UV exposure pattern. The UV exposure causes the SR 103 to be cured, the cured SR 104 is indicated with the dappled pattern. An area protected from (excluded from) UV exposure results in a region 108 of uncured SR. Embodiment 150, with the cartoon arrow, depicts the thinning of the region 108 of uncured SR. The resulting “thin layer of SR” has a thickness defined by an initial thickness 156 reduced by amount 152. The SR thinning can be achieved with a partial develop process such as a wet chemistry etch. This includes a layer-by-layer develop which allows for control of the final Z-height or thickness of the undeveloped SR. This layer-by-layer process contrasts with available solutions that implement a “swelling” type of develop mechanism, which has limited to no control over the final Z-height of the undeveloped SR.

Embodiment 170 depicts a second UV 172 exposure, directed to the region 108 of uncured SR, resulting in a cured thin layer 174 of SR. When performed across an entire wafer or panel, embodiments exhibit a very uniform consistency and control of the thinned SR. In a non-limiting example, the initial thickness is 33 microns, and the average thickness of the “cured thin layer 174 of SR” implemented at multiple points across a panel is 4.2 microns with a standard deviation of 0.25 microns.

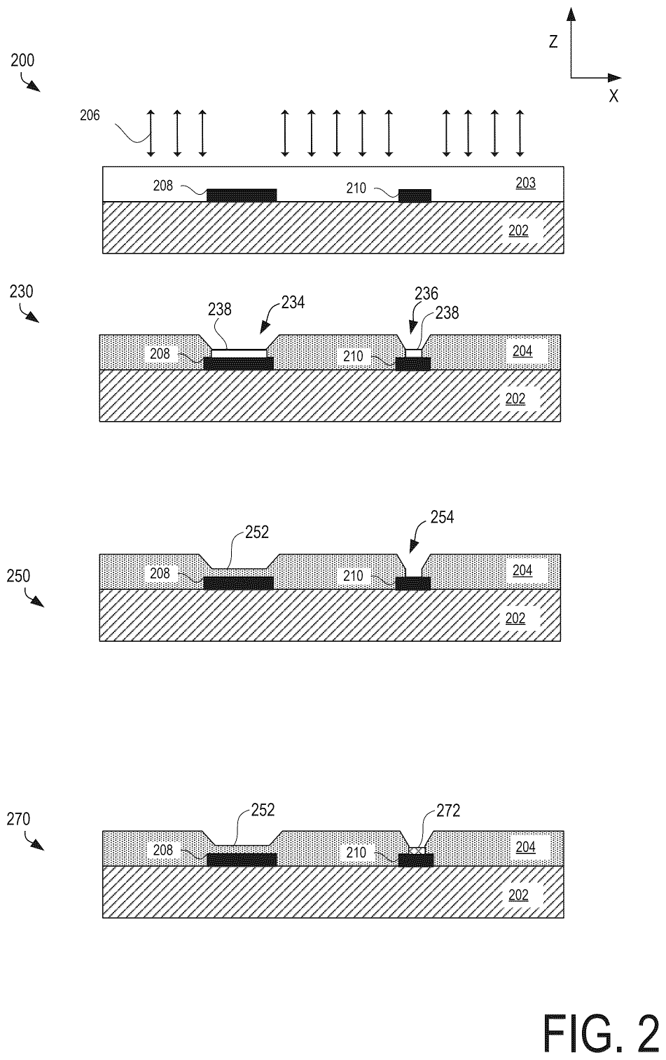

FIG. 2 illustrates the application of the thinnable resist develop process of FIG. 1 to a shallow fid process. The FIG. 2 illustrations are cross-sectional images, with a Z-X frame of reference, as indicated. The uncured thinnable SR layer 203 is on the substrate material 202. A first conductive contact 208 and a second conductive contact 210 are illustrated. The conductive contacts comprise conductive material, generally a metal, such as copper (Cu). While the illustrations are not to scale, it is intentional that the first conductive contact 208 is wider than the second conductive contact 210; for example, to represent different pitch sizes. In a non-limiting example, the first conductive contact 208 represents a first pitch and the second conductive contact 210 represents a pitch for a micro-ball, wherein the first pitch is larger/coarser than the micro-ball pitch. The upper surface of the uncured thinnable SR layer 203 is UV 206 exposed, selectively, such that target regions, e.g., the region above the first conductive contact 208 and the region above the second conductive contact 210, are not exposed to UV.

Embodiment 230 illustrates the architecture after thinning the uncured SR in the target regions, showing a thinned region 234 over the first conductive contact 208 and a thinned region 236 over the second conductive contact 210. The thinning process is as described in connection with FIG. 1. Note that the thinned regions each comprise a thin layer 238 of uncured SR. When this process is implemented across a wafer or panel, there is a uniformity of the thin layer of SR, as described above.

Embodiment 250 depicts how the architecture may look after UV radiation and thermal curing. A thin layer 252 of SR remains on the first conductive contact. The thickness of the “thin” layer 252 of SR is as described in connection with FIG. 1. In some embodiments, the second conductive contact 210 also has a thin layer of SR on it. In other embodiments, the SR thinning and curing process may remove the thin layer 238 of uncured SR in the second conductive contact 254 (the smaller of the two, e.g., the micro-ball pitch).

Embodiment 270 illustrates the architecture of embodiment 250 with an organic surface protection (OSP) layer 272 on the second conductive contact 210. In some embodiments, the OSP layer comprises an organic material such as an imidazole-based material. In summary, by applying the thinnable resist develop process to a shallow fid process (as shown in embodiment 270) a thin layer 252 of SR remains on top of the copper or conductive contact 208. This thin layer 252 SR remedies the Cu oxidation issue and thereby improves the fid recognition.

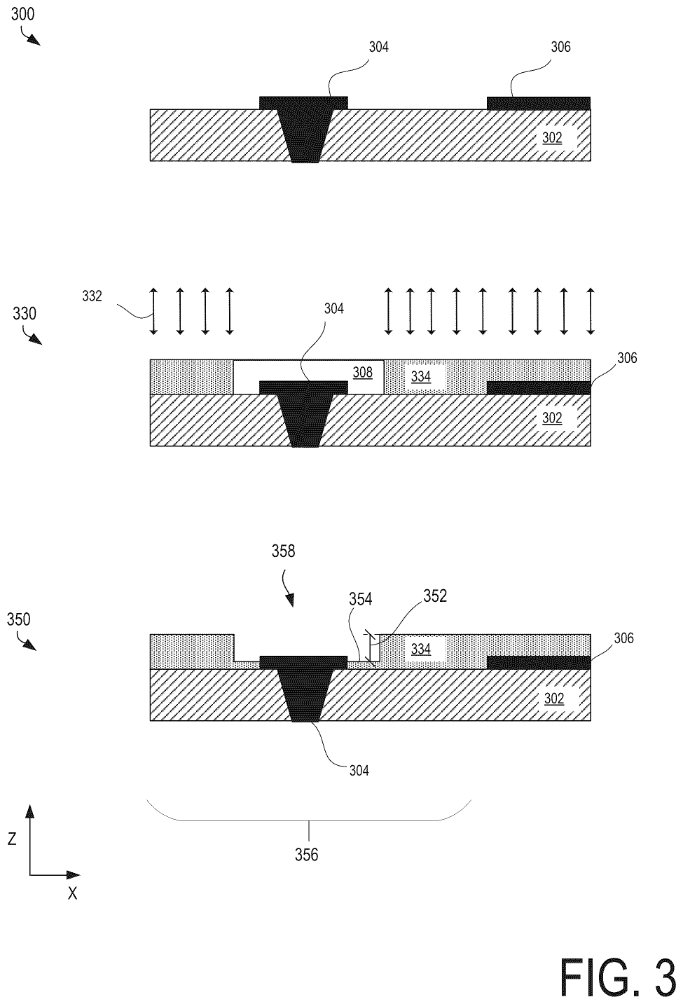

FIG. 3, FIG. 4A and FIG. 4B illustrate the application of the thinnable resist develop process of FIG. 1 to a metal defined (MD) pad process. The FIG. 3 illustrations are cross-sectional images, with a Z-X frame of reference, as indicated. The FIG. 4A illustration is a cross-sectional image with a Z-X frame of reference, and FIG. 4B is a top-down image with a Y-X frame of reference, both as indicated. The substrate 302 may be a semiconductor substrate comprising an integrated circuit and layer of dielectric material at its upper surface. Surface metal comprising one or a plurality of conductive contact(s) 304 and a trace 306 is patterned on the substrate 302 or ABF using lithography and electrolytic plating, followed by a flash seed etch, as is known in the art. While available approaches generally utilize palladium (Pd) as a catalyst during flash seed etch, the provided embodiments do not require or use Pd in the flash seed etch process.

Embodiment 330 depicts the SR lamination of the upper surface of the substrate 302/402 and selective UV 332 exposure of the layer of SR 334, that leaves a target region 308 uncured. The region 308 of uncured SR is on the conductive contact 304. Embodiment 350 depicts the architecture of embodiment 330 after the region 308 of uncured SR has been thinned an amount 352 and exposed to UV to thermal cure it. In various embodiments, the SR thinning may be performed by a controllable SR thinning process that uses immersion or spray development with an aqueous basic solution and deionized (DI) water spray. The aqueous basic solution contains inorganic bases or organic bases. The chemistry of the aqueous basic solution can attack solder resist progressively, which is in contrast to available approaches that perform a fast penetration of the entire SR layer. The proposed aqueous basic solution enables using an immersion time to control how much SR is being is removed to thereby achieve the desired thinning.

After the SR is thinned, the resulting thin layer of uncured SR is in a region around a periphery of the conductive contact 304, and the conductive contact extends above the thin layer of SR. Said differently, the conductive contact is exposed at the upper surface, having no SR on top if its upper surface, as shown in embodiment 350. The thin layer of uncured SR is exposed to the second UV exposure and a thermal cure. Subsequent to the thinning and second UV exposure, a thin layer 354/454 of SR surrounds the conductive contact 304/404, and the exposed conductive contact 304/404 is in a cavity 358 formed in cured SR 334/434 with no exposed substrate 302/402 material. The region indicated with bracket 356 is enlarged in FIGS. 4A and 4B to better illustrate features of the embodiments.

FIG. 4A illustrates a cross sectional view 400 and FIG. 4B illustrates a top-down view 470 of a finalized architecture for an individual MD patterned conductive contact 304/404, in accordance with various embodiments. Said differently, embodiment 400 depicts an architecture or apparatus that can be achieved using the herein described SR thinning process. Embodiments exhibit a cavity 358/458 in the SR 434 wherein a cavity sidewall meets the cavity floor (thereby forming a corner, indicated with arrow 462) around the perimeter of the cavity floor, wherein the cavity sidewall, corner, and cavity floor all comprise the same SR 434. The cavity sidewalls are substantially perpendicular to the cavity floor, plus or minus 15 degrees from 90 degrees. The cavity sidewalls additionally appear in cross sectional images as having a regular slope from the upper surface to the cavity floor, without any undercuts, caves, or bulges. Embodiments can be detected in a SEM or TEM image when there is a continuous SR 434 material for both the cavity sidewall and cavity bottom surrounding the conductive contact 304/404, as indicated with the patterned shading. In contrast, without practicing this controllable SR thinning process, the cavity sidewall comprises SR 434, but the cavity floor, surrounding the conductive contact 304/404, comprises ABF or whatever material makes up the substrate 302/402, which is distinctly not SR 434, and the corner encircling the conductive contact is instead a weak point for SR 434 adhesion to the ABF or material making up the substrate 402.

As described above, the thin layer 354/454 of SR has a thickness equal to the initial thickness 453 minus the thinned amount 452; moreover, the region of thin layer 454 of SR surrounds the conductive contact 304/404 radially, as seen in top-down view 470. The thickness external to the cavity (i.e., that of the initial or non-thinned SR) can vary but embodiments exhibit the thinned SR as described herein. In various embodiments, the conductive contact 304/404 is electroless plated with NiPdAu (nickel, palladium, gold), meaning that it has a layer of NiPdAu 456 directly on the material of the conductive contact 304/404, as shown. Embodiments have a gap 460 or distance between the plated conductive contact 304/404 and the sidewall of the SR 434, in other words, in a cross-sectional image, the layer of NiPdAu 456 does not completely cover the cavity floor, and it does not contact the sidewalls, as illustrated. The conductive contacts may be to accommodate solder balls at a pitch of 0.2 to 0.6 millimeters; accordingly, individual cavities and gaps scale to accommodate one solder ball per conductive contact or cavity, in the given pitch. The sidewall represents the transition (as the eye moves laterally across the image) between the thinned SR and the initial thickness SR, or the transition between the first thickness and the second thickness. In embodiments in which a plurality of conductive contacts is processed concurrently, there is a respective plurality of thinned SR regions and a remainder of the dielectric or non-conductive material has the second thickness (initial thickness).

Upon examination of final products, embodiments have sidewalls that are substantially perpendicular from the upper surface to the cavity floor and do not exhibit SR undercut regions (the SR undercut region would appear as a bulged out/caved-in portion at the base of the cavity sidewall, deviating from a regular slope, i.e., at the corner 462), SR undercut regions arc undesirable because they can become a dead spot causing a flux and/or solder residue trap, or cause other solder ball formation issues. The SR undercuts undesirably lead to issues with SR adhesion and solder ball isolation or “satellite” issues. Also, upon examination, embodiments do not exhibit pad cracks (which would be observed in the areas 464, even after thermal cycling tests.

In summary, the provided MD pad process flow using thinnable SR is distinguishable because it leaves a thin layer 454 of SR around the MD pad 458 area. This thin layer 454 of SR remedies the MD pad crack issue observed post reflow in other MD pad processes. This thinnable SR process can also reduce or remove SR adhesion, SR undercut, and solder ball satellite issues.

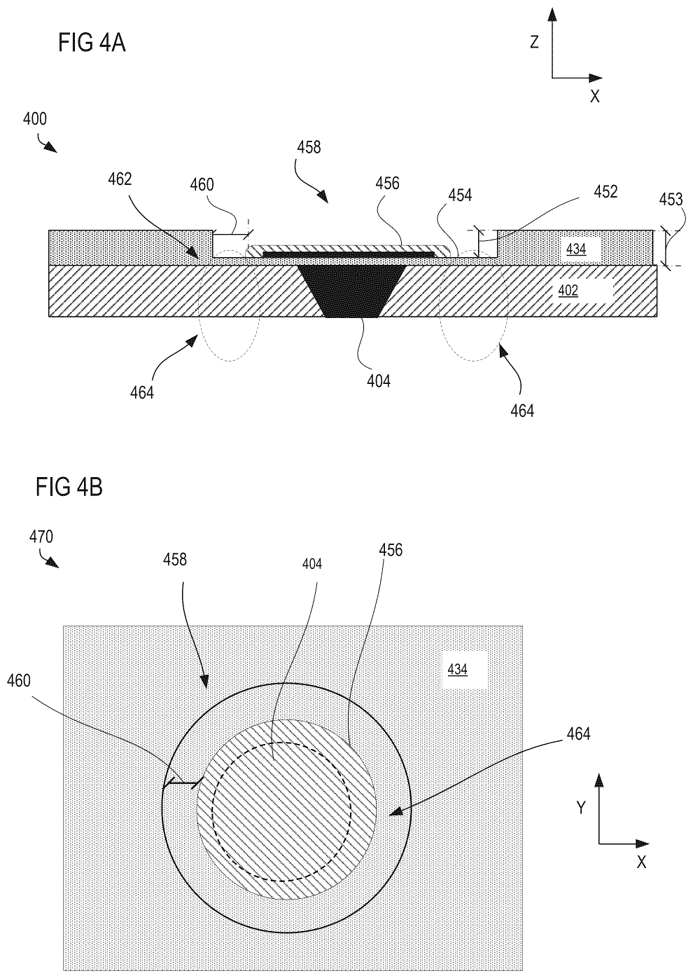

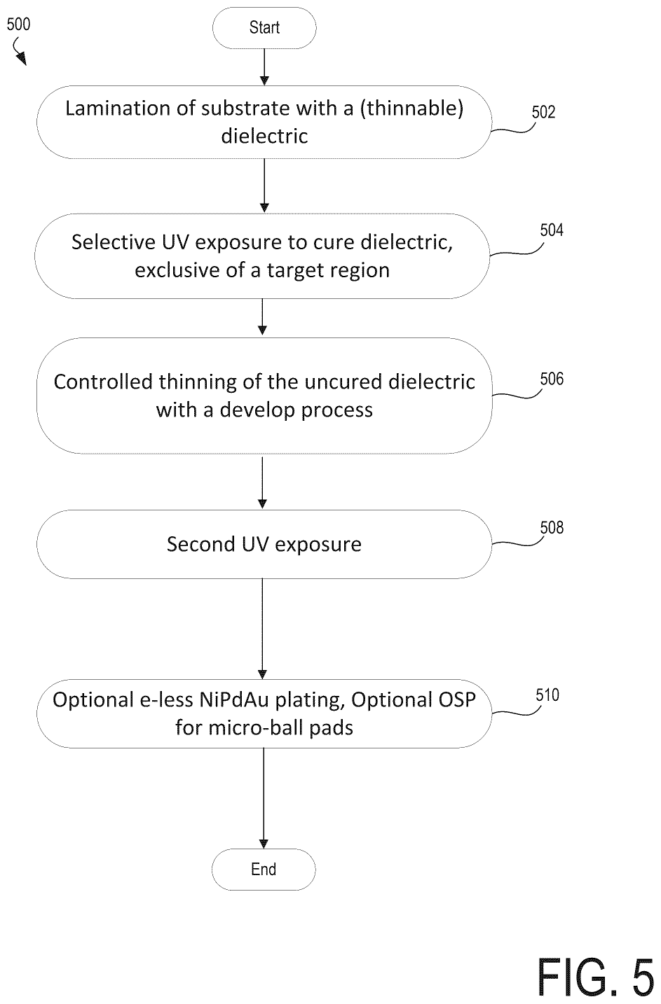

FIG. 5 is a method 500 for shallow fiducial and metal defined pad designs, in accordance with embodiments described herein. The process incorporates a thinnable resist develop process, as described in connection with FIG. 1. Prior to starting the method, a silicon substrate is created/manufactured that includes an integrated circuit and has one or a plurality of conductive contacts on an upper surface.

At 502, the silicon substrate is laminated with a thinnable dielectric or solder resist (SR). Said differently, at 502, a layer of SR is placed or overlaid on an upper surface of the substrate. Depending on the application, the silicon substrate may have a copper or conductive contact on its surface, it may also have a conductive trace on its upper surface. In various embodiments, the substrate is a portion of a wafer or a panel, and the substrate further has a plurality of conductive contacts on its upper surface.

At 504, the laminated substrate is subjected to selective UV exposure and thermal curing, such that one or more target areas of the SR remain uncured (see, e.g., embodiments 130, 230, and 330).

At 506, the laminated substrate is subjected to controlled thinning of the uncured dielectric using a develop process (see, e.g., see embodiment 150). In various embodiments, the develop process comprises a wet chemistry treatment time, a temperature, a concentration, and a pressure; and by controlling those variables, the final thickness of the uncured SR ca be controlled (as described above, this final thickness is also referred to as the thickness of the thin layer of SR). Also, as mentioned above, the develop process further can achieve a very flat/uniform surface across individual instances of thin layer of SR as well as across multiple instances of the thin layer of SR across a wafer or a panel. In various embodiments, the final thickness of the thin layer of SR can be controlled within plus or minus 1 micron across an entire wafer or panel.

At 508, a second UV exposure is performed to cure the thin layer of uncured dielectric or SR. At 510, for shallow fid processes, optional OSP can be placed on the copper or conductive contact. Optionally, at 510, for MD pad processes, the electroless plating of the conductive contact with NiPdAu may be performed.

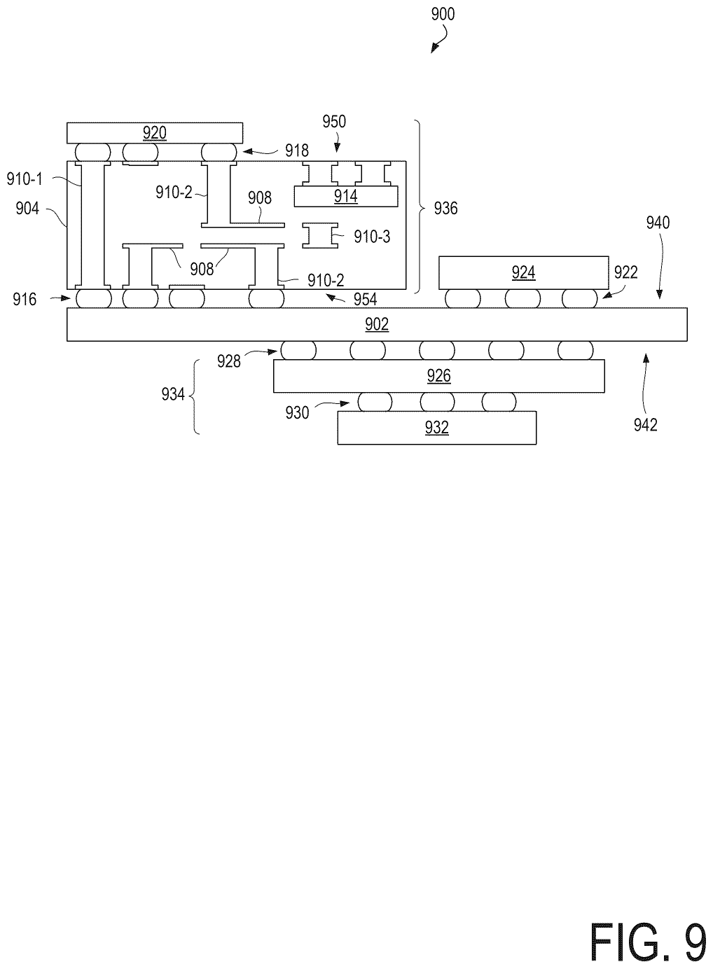

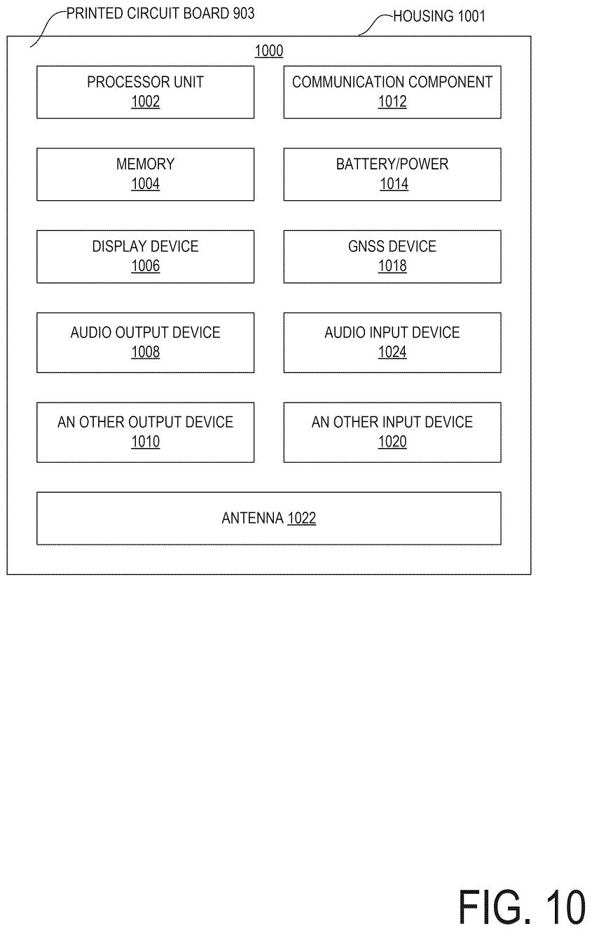

After 510, the method 500 may end or the apparatus created by the method 500 may be subjected to further processing and/or manufacturing to create a multi-die assembly/microelectronic assembly (see, e.g., FIG. 9, microelectronic assembly 900), or a product or device (see, FIG. 10 electrical device 1000). Any of the embodiments may be found in dies that are assembled onto an organic substrate or printed circuit board (PCB) in a package or device. Embodiments may be combined with one or more additional integrated circuit (IC) die and may also be attached to the organic substrate/PCB/circuit board 902, and the entire silicon complex can be encapsulant with a mold or polymer underfill material. Other encapsulants can comprise a dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a multi-die package. As part of a thermal management solution, a thermal conduction layer interface material (TIM) may be located over the die. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

Thus, methods and architectures for shallow fiducial and metal defined pad designs using a thinnable dielectric or solder resist have been described herein. The methods and apparatus controllably thin SR and leverage the properties of the non-conductive dielectric or SR to protect copper and conductive pads from oxidation, SR undercut incidents, and MD pad cracks. The following description and associated figures provide more detail for components referenced hereinabove.

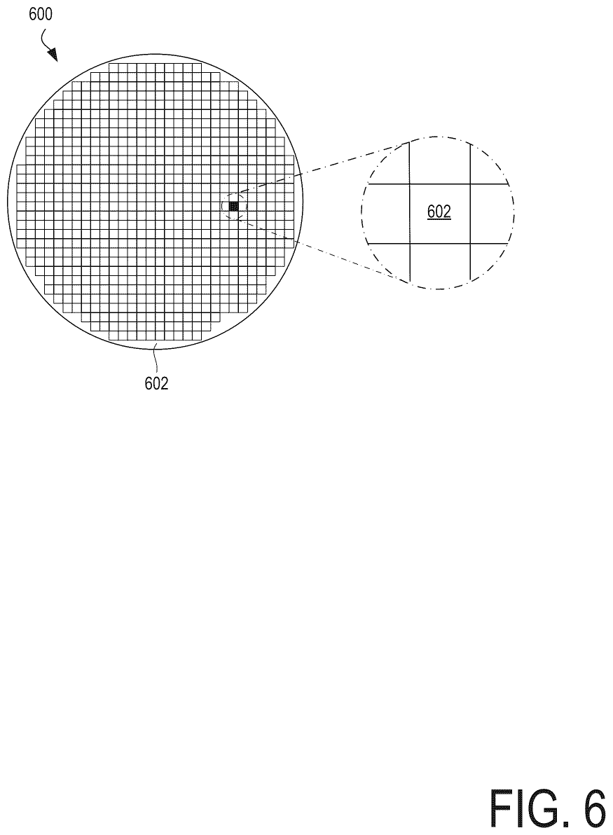

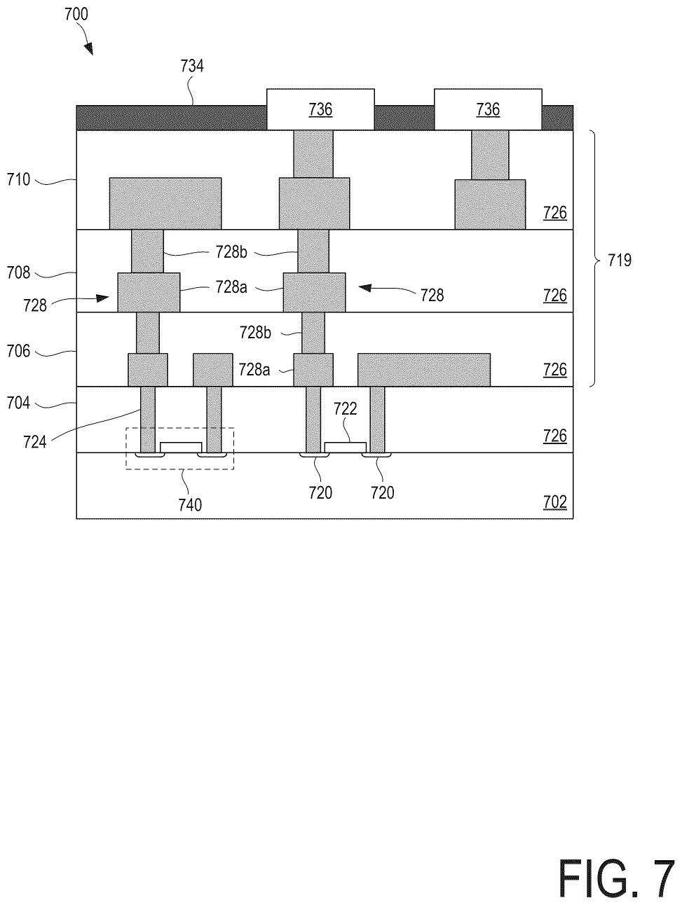

FIG. 6 is a top view of a wafer 600 and dies 602 that may be included in any of the embodiments disclosed herein. The wafer 600 may be composed of semiconductor material and may include one or more dies 602 formed on a surface of the wafer 600. After the fabrication of the integrated circuit components on the wafer 600 is complete, the wafer 600 may undergo a singulation process in which the dies 602 are separated from one another to provide discrete “chips” or destined for a packaged integrated circuit component. The individual dies 602, comprising an integrated circuit component, may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 602. For example, a memory array formed by multiple memory devices may be formed on a same die 602 as a processor unit (e.g., the processor unit 1002 of FIG. 10) or other logic that is configured to store information in the memory devices or execute instructions stored in the memory array. In some embodiments, a die 602 may be attached to a wafer 600 that includes other die, and the wafer 600 is subsequently singulated, this manufacturing procedure is referred to as a die-to-wafer assembly technique.

FIG. 7 is a cross-sectional side view of an integrated circuit 700 that may be included in any of the embodiments disclosed herein. One or more of the integrated circuits 700 may be included in one or more dies 602 (FIG. 6). The integrated circuit 700 may be formed on a die substrate 702 (e.g., the wafer 600 of FIG. 6) and may be included in a die (e.g., the die 602 of FIG. 6).

The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit 700 may be used. The die substrate 702 may be part of a singulated die (e.g., the dies 602 of FIG. 6) or a wafer (e.g., the wafer 600 of FIG. 6).

The integrated circuit 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720.

The gate 722 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may comprise a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be conducted to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuits having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728a/b of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit 700 with another component (e.g., a printed circuit board). The integrated circuit 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit 700 is a double-sided die, the integrated circuit 700 may include another metallization stack (not shown) on the opposite side of the device layer(s) 704. This metallization stack may include multiple interconnect layers as discussed above with reference to the interconnect layers 706-710, to provide electrically conductive paths (e.g., including conductive lines and vias) between the device layer(s) 704 and additional conductive contacts (not shown) on the opposite side of the integrated circuit 700 from the conductive contacts 736.

In other embodiments in which the integrated circuit 700 is a double-sided die, the integrated circuit 700 may include one or more through-silicon vias (TSVs) through the die substrate 702; these TSVs may make contact with the device layer(s) 704, and may provide electrically conductive paths between the device layer(s) 704 and additional conductive contacts (not shown) on the opposite side of the integrated circuit 700 from the conductive contacts 736. In some embodiments, TSVs extending through the substrate can be used for routing power and ground signals from conductive contacts on the opposite side of the integrated circuit 700 from the conductive contacts 736 to the transistors 740 and any other components integrated into the die of the integrated circuit 700, and the metallization stack 719 can be used to route I/O signals from the conductive contacts 736 to transistors 740 and any other components integrated into the die of the integrated circuit 700.

Multiple integrated circuits 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

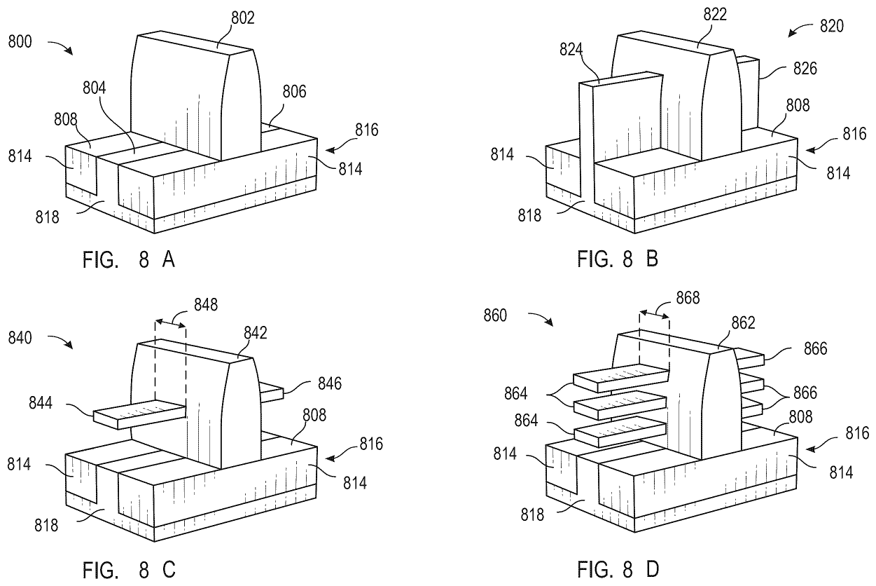

FIGS. 8A-8D are simplified perspective views of example planar, FinFET, gate-all-around, and stacked gate-all-around transistors. The transistors illustrated in FIGS. 8A-8D are formed on a substrate 816 having a surface 808. Isolation regions 814 separate the source and drain regions of the transistors from other transistors and from a bulk region 818 of the substrate 816.

FIG. 8A is a perspective view of an example planar transistor 800 comprising a gate 802 that controls current flow between a source region 804 and a drain region 806. The transistor 800 is planar in that the source region 804 and the drain region 806 are planar with respect to the substrate surface 808.

FIG. 8B is a perspective view of an example FinFET transistor 820 comprising a gate 822 that controls current flow between a source region 824 and a drain region 826. The transistor 820 is non-planar in that the source region 824 and the drain region 826 comprise “fins” that extend upwards from the substrate surface 808. As the gate 822 encompasses three sides of the semiconductor fin that extends from the source region 824 to the drain region 826, the transistor 820 can be considered a tri-gate transistor. FIG. 8B illustrates one S/D fin extending through the gate 822, but multiple S/D fins can extend through the gate of a FinFET transistor.

FIG. 8C is a perspective view of a gate-all-around (GAA) transistor 840 comprising a gate 842 that controls current flow between a source region 844 and a drain region 846. The transistor 840 is non-planar in that the source region 844 and the drain region 846 are elevated from the substrate surface 808.

FIG. 8D is a perspective view of a GAA transistor 860 comprising a gate 862 that controls current flow between multiple elevated source regions 864 and multiple elevated drain regions 866. The transistor 860 is a stacked GAA transistor as the gate controls the flow of current between multiple elevated S/D regions stacked on top of each other. The transistors 840 and 860 are considered gate-all-around transistors as the gates encompass all sides of the semiconductor portions that extend from the source regions to the drain regions. The transistors 840 and 860 can alternatively be referred to as nanowire, nanosheet, or nanoribbon transistors depending on the width (e.g., widths 848 and 868 of transistors 840 and 860, respectively) of the semiconductor portions extending through the gate.

FIG. 9 is a cross-sectional side view of a microelectronic assembly 900 that may include any of the embodiments disclosed herein. The microelectronic assembly 900 includes multiple integrated circuit components disposed on a circuit board 902 (which may be a motherboard, system board, mainboard, etc.). The microelectronic assembly 900 may include components disposed on a first face 940 of the circuit board 902 and an opposing second face 942 of the circuit board 902; generally, components may be disposed on one or both faces 940 and 942.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The microelectronic assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpackaged integrated circuit component that includes one or more integrated circuit dies (e.g., the die 602 of FIG. 6, the integrated circuit 700 of FIG. 7) and/or one or more other suitable components.

The unpackaged integrated circuit component 920 comprises solder bumps attached to contacts on the die. The solder bumps allow the die to be directly attached to the interposer 904. In embodiments where the integrated circuit component 920 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through-silicon vias (TSV) extending through the silicon interposer can connect connections on the first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The integrated circuit assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the embodiments disclosed herein. For example, any suitable ones of the components of the electrical device 1000 may include one or more of the disclosed embodiments, semiconductor assemblies, package assemblies, microelectronic assemblies 900, integrated circuit components 920, integrated circuits 700, integrated circuit dies 602, or structures disclosed herein. A number of components are illustrated in FIG. 10 as included in the electrical device 1000, but any one or more of these components may be omitted or duplicated, as suitable for the application. In some embodiments, some or all the components included in the electrical device 1000 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1000 can comprise one or more processor units 1002 that are heterogeneous or asymmetric to another processor unit 1002 in the electrical device 1000. There can be a variety of differences between the processor units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include power supply such as a battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Similarly, the word “overlaid” is used herein to denote a spatial relationship, being the past tense of overlay, to have been spread across, or superimposed on an object. Overlaid does not imply any particular procedure for placement. If a first layer is overlaid on a second layer, the first layer is also “located on” the second layer, as defined above.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (cither directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a substrate comprising a layer of dielectric material; a conductive contact on the substrate; and a layer of non-conductive material adjacent to the substrate and over the conductive contact; wherein the layer of non-conductive material has a region around the conductive contact with a first thickness and external to the region the non-conductive material is a second thickness that is greater than the first thickness.
Example 2 includes the subject matter of Example 1, wherein the layer of non-conductive material comprises solder resist.
Example 3 includes the subject matter of Example 1 or Example 2, wherein the first thickness is 4.2 microns plus or minus 0.25 microns.
Example 4 includes the subject matter of any one of Examples 1-3, wherein the conductive contact comprises copper.
Example 5 includes the subject matter of any one of Examples 1-4, wherein the layer of non-conductive material is cured.
Example 6 includes the subject matter of any one of Examples 1-5, wherein the dielectric material comprises Ajinomoto build-up film
Example 7 includes the subject matter of any one of Examples 1-6, wherein the conductive contact is one of a plurality of conductive contacts, individual conductive contacts are on the substrate and under the layer of non-conductive material; and wherein the layer of non-conductive material has, for individual conductive contacts of the plurality of conductive contacts, a respective region with the first thickness.
Example 8 includes the subject matter of any one of Examples 1-7, wherein a transition between the first thickness and the second thickness defines a sidewall of a cavity, and wherein the region around the conductive contact extends from a peripheral edge of the conductive contact to the sidewall and excludes an upper surface of the conductive contact.
Example 9 includes the subject matter of Example 8, further comprising: a layer including nickel, palladium, and gold that extends across an upper surface of the conductive contact; and a gap formed between the sidewall and the layer of nickel, palladium, and gold.
Example 10 includes the subject matter of any one of Examples 1-7, wherein the region around the conductive contact includes an upper surface of the conductive contact.
Example 11 is a semiconductor assembly including: a semiconductor substrate comprising an integrated circuit and a plurality of conductive contacts on an upper surface; a layer of non-conductive material adjacent to the semiconductor substrate and over the plurality of conductive contacts; wherein the layer of non-conductive material has a first thickness of 4.2 microns plus or minus 0.25 microns above individual conductive contacts of the plurality of conductive contacts, and a second thickness that is greater than the first thickness; and a plurality of solder balls, individual solder balls of the plurality of solder balls attached to a respective one of the plurality of conductive contacts.
Example 12 includes the subject matter of Example 11, wherein the dielectric material comprises Ajinomoto build-up film.
Example 13 includes the subject matter of Example 11, wherein the plurality of conductive contacts comprise copper.
Example 14 includes the subject matter of Example 11, wherein the layer of non-conductive material comprises polyimide.
Example 15 includes the subject matter of Example 11, wherein the layer of non-conductive material is cured.
Example 16 includes the subject matter of any one of examples 11-15, further comprising a printed circuit board attached to the plurality of solder balls.
Example 17 includes the subject matter of Example 16, wherein the integrated circuit is a processing unit, and further comprising a memory storage device attached to the printed circuit board and in operable communication with the processing unit.
Example 17 includes the subject matter of Example 17, further comprising a power supply attached to the printed circuit board.
Example 19 is a method comprising: creating a silicon substrate comprising an integrated circuit and an upper surface with a plurality of conductive contacts; placing a layer of an uncured non-conductive material adjacent to the silicon substrate; curing the layer of non-conductive material, wherein curing excludes, for individual conductive contacts of the plurality of conductive contacts, a respective region; thinning the uncured non-conductive material subsequent to the curing; and curing thinned uncured non-conductive material.
Example 20 includes the subject matter of Example 19, wherein thinning includes a wet chemistry process with an aqueous basic solution and deionized (DI) water spray.
Example 21 includes the subject matter of Example 19, wherein thinning includes reducing a thickness to 4.2 microns plus or minus 0.25 microns.

What is claimed is:

1. An apparatus, comprising:
a substrate comprising a layer of dielectric material;
a conductive contact on the substrate; and
a layer of non-conductive material over the substrate and adjacent the conductive contact;
wherein the layer of non-conductive material has a region around the conductive contact with a first thickness and external to the region the non-conductive material is a second thickness that is greater than the first thickness.

2. The apparatus of claim 1, wherein the layer of non-conductive material comprises solder resist.

3. The apparatus of claim 1, wherein the first thickness is 4.2 microns plus or minus 0.25 microns.

4. The apparatus of claim 1, wherein the conductive contact comprises copper.

5. The apparatus of claim 1, wherein the layer of non-conductive material is cured.

6. The apparatus of claim 1, wherein the dielectric material comprises Ajinomoto build-up film.

7. The apparatus of claim 1, wherein the conductive contact is one of a plurality of conductive contacts, individual conductive contacts are on the substrate and under the layer of non-conductive material; and
wherein the layer of non-conductive material has, for individual conductive contacts of the plurality of conductive contacts, a respective region with the first thickness.

8. The apparatus of claim 1, wherein a transition between the first thickness and the second thickness defines a sidewall of a cavity, and wherein the region around the conductive contact extends from a peripheral edge of the conductive contact to the sidewall and excludes an upper surface of the conductive contact.

9. The apparatus of claim 8, further comprising:
a layer including nickel, palladium, and gold that extends across an upper surface of the conductive contact; and
a gap formed between the sidewall and the layer of nickel, palladium, and gold.

10. The apparatus of claim 1, wherein the region around the conductive contact includes an upper surface of the conductive contact.

11. A semiconductor assembly including:
a semiconductor substrate comprising an integrated circuit and a plurality of conductive contacts on an upper surface;
a layer of non-conductive material over the semiconductor substrate and adjacent the plurality of conductive contacts;
wherein the layer of non-conductive material has a first thickness of 4.2 microns plus or minus 0.25 microns above individual conductive contacts of the plurality of conductive contacts, and a second thickness that is greater than the first thickness; and
a plurality of solder balls, individual solder balls of the plurality of solder balls attached to a respective one of the plurality of conductive contacts.

12. The semiconductor assembly of claim 11, wherein the semiconductor substrate comprises Ajinomoto build-up film.

13. The semiconductor assembly of claim 11, wherein the plurality of conductive contacts comprise copper.

14. The semiconductor assembly of claim 11, wherein the layer of non-conductive material comprises polyimide.

15. The semiconductor assembly of claim 14, wherein the layer of non-conductive material is cured.

16. The semiconductor assembly of claim 14, further comprising a printed circuit board attached to the plurality of solder balls.

17. The semiconductor assembly of claim 16, wherein the integrated circuit is a processing unit, and further comprising a memory storage device attached to the printed circuit board and in operable communication with the processing unit.

18. The semiconductor assembly of claim 17, further comprising a power supply attached to the printed circuit board.

19. A method comprising:
creating a silicon substrate comprising an integrated circuit and an upper surface with a plurality of conductive contacts;
placing a layer of an uncured non-conductive material adjacent the silicon substrate;
curing the layer of non-conductive material, wherein curing excludes, for individual conductive contacts of the plurality of conductive contacts, a respective region;
thinning the uncured non-conductive material subsequent to the curing; and
curing thinned uncured non-conductive material.

20. The method of claim 19, wherein thinning includes a wet chemistry process with an aqueous basic solution and deionized (DI) water spray; and
wherein thinning includes reducing a thickness to 4.2 microns plus or minus 0.25 microns.
